(19) United States
(12) Patent Application Publication
(10) Pub. No.: US 2026/0223627 A1
(43) Pub. Date: Jul. 30, 2026

(54) OPTICAL HEATING APPARATUS

(71) Applicant: Ushio Denki Kabushiki Kaisha, Tokyo (JP)

(72) Inventor: Yoshimasa IKE, Tokyo (JP)

(73) Assignee: Ushio Denki Kabushiki Kaisha, Tokyo (JP)

(21) Appl. No.: 19/425,737

(22) Filed: Dec. 18, 2025

(30) Foreign Application Priority Data
Jan. 28, 2025 (JP) 2025-011935

(51) Int. Cl. H10P 72/00

(52) U.S. Cl. CPC H10P 72/0436

(57) ABSTRACT

Providing an optical heating apparatus capable of increasing the illuminance of heating light to be applied to a central portion of a substrate to be treated, even in a case where there is a restriction on the disposition of an LED element in a region that faces the central portion. The optical heating apparatus includes: a support unit that supports the substrate to be treated; a light source unit that includes an LED substrate that is disposed to face the substrate to be treated, and a plurality of LED elements; and an optical system that refracts at least a portion of light emitted by the plurality of LED elements, toward a central portion of the substrate to be treated, wherein the light source unit is configured to include a space facing the substrate to be treated at least in a vicinity of a normal of the substrate.

### CROSS-REFERENCE TO RELATED APPLICATIONS

This application claims priority of Japan Patent Application No. 2025-011935, which was filed on Jan. 28, 2025, and which is incorporated herein in its entirety by reference.

### BACKGROUND OF THE INVENTION

### Field of the Invention

The present invention relates to an optical heating apparatus that irradiates a substrate to be treated with light for heating (hereinafter referred to as “heating light” for convenience) to heat the substrate to be treated.

### Description of the Related Art

In a semiconductor manufacturing process, a variety of treatments, such as film deposition, oxidation and diffusion, modification, or annealing, are performed on a substrate to be treated such as a semiconductor wafer. In these treatments, a heating method for irradiating a main surface of the substrate to be treated with heating light is often employed, because treatment can be performed in a non-contact manner. Here, the “main surface” refers to a surface having a much larger area than the other surfaces from among surfaces constituting a plate-shaped object.

Patent Document 1 below discloses an optical heating apparatus that performs heating treatment on a semiconductor wafer by using light emitted from an LED element.

### PRIOR ART DOCUMENT

### Patent Document

Patent Document 1: JP-A-2018-523305

### SUMMARY OF THE INVENTION

It is expected that a device that irradiates a substrate to be treated that is used in a semiconductor manufacturing process with light is capable of irradiating the entirety of a surface (in particular, a main surface) of the substrate to be treated with light having an identical intensity such that the entirety of the substrate to be treated is uniformly treated.

Meanwhile, in recent years, treatment performed on a substrate to be treated has been diversified, and in some cases, an aspect of disposition of an LED element is restricted due to the disposition of equipment configured to perform the treatment in a position facing a semiconductor wafer.

For example, there is a cleaning process for cleaning the main surface of the substrate to be treated with cleaning solution while heating the substrate to be treated. In such a cleaning process, typically, a nozzle configured to drop the cleaning solution is disposed to face a central portion of the substrate to be treated. Furthermore, examples of the equipment that is disposed to face the central portion of the substrate to be treated include a temperature sensor or an infrared camera that monitors the temperature of the substrate to be treated in real time, a gas supply nozzle configured to supply process gas or reactant gas, and a rotation mechanism configured to rotate the substrate to be treated.

In a case where equipment for treatment is disposed in a region that faces the central portion of the substrate to be treated, it is difficult to dispose the LED element in the region that faces the central portion. In particular, in a case where the LED element fails to be disposed in the region that faces the central portion, light applied to the central portion is likely to be insufficient. As a result, it becomes difficult to uniformly heat the main surface of the substrate to be treated, and it becomes difficult to uniformly treat the entirety of the substrate to be treated.

Accordingly, there is a request for an optical heating apparatus that is capable of increasing the illuminance of heating light to be applied to a central portion of a substrate to be treated, such as a semiconductor wafer, even in a case where there is a restriction on the disposition of an LED element in a region that faces the central portion.

In view of the circumstances described above, an object of the present invention is to provide an optical heating apparatus that is capable of increasing the illuminance of heating light to be applied to a central portion of a substrate to be treated, even in a case where there is a restriction on the disposition of an LED element in a region that faces the central portion.

An optical heating apparatus according to the present invention is an optical heating apparatus that irradiates a substrate to be treated with light, and heats the substrate to be treated, the optical heating apparatus including: a support unit that supports the substrate to be treated; a light source unit that includes an LED substrate that is disposed to face a portion of a main surface of the substrate to be treated, and a plurality of LED elements that is placed on the LED substrate; and an optical system that is disposed between the substrate to be treated and the LED substrate, and refracts at least a portion of light emitted by the plurality of LED elements, toward a central portion of the substrate to be treated, wherein the light source unit is configured to include a space facing the substrate to be treated at least in a vicinity of a normal passing through a center of the main surface of the substrate to be treated.

The phrase “the light source unit is configured to include a space facing the substrate to be treated” means that there is a region where the light source unit and the substrate to be treated do not overlap with each other in a normal direction of the main surface of the substrate to be treated. In other words, the light source unit includes a space that faces the substrate to be treated along the normal. Furthermore, the “vicinity of the normal” refers to a region where a distance from the normal in a radial direction of the substrate to be treated is 25% or less of the diameter of the substrate to be treated.

In a case where the LED substrate faces a portion of the main surface of the substrate to be treated and the light source unit includes a space facing the substrate to be treated at least in the vicinity of the normal direction of the main surface of the substrate to be treated, an aspect of disposition of the LED elements is restricted. In particular, when the light source unit includes the space in the vicinity of the normal passing through the center of the substrate to be treated, it is difficult to dispose the LED elements in a region that faces the central portion of the substrate to be treated, and light to be applied to the central portion is likely to be insufficient. In contrast, by employing the configuration described above, the optical system is disposed for the LED element, heating light emitted by the LED element is refracted toward the central portion, and the illuminance of heating light to be applied to the central portion is increased. As a result, even in a case where there is a restriction on the disposition of the LED elements in the region that faces the central portion, the illuminance of heating light to be applied to the central portion can be suitably increased.

The present invention is not limited to a configuration of equipment that is disposed in the space included in the light source unit (hereinafter referred to as a “communication space”, for convenience). A specific example will be described later in the section “DETAILED DESCRIPTION OF THE PREFERRED EMBODIMENTS”.

In the optical heating apparatus, the optical system may include a plurality of converging optical elements that is disposed to individually correspond to the plurality of LED elements, the plurality of converging optical elements each reducing a divergence angle of the light emitted by each of the plurality of LED elements, and when viewed in a normal direction of the main surface of the substrate to be treated, a focal point of each of the plurality of converging optical elements may be located closer to the center of the substrate to be treated than the center of a light-emitting surface of the LED element that each of the plurality of converging optical elements corresponds to.

From the viewpoint of irradiating the central portion of the substrate to be treated with a larger amount of heating light, it is preferable that the optical system include a converging optical element that reduces a divergence angle of heating light. In addition, by causing the focal point of the converging optical element to be located as described above, a large amount of heating light emitted by the LED element can be guided toward the central portion of the substrate to be treated.

Furthermore, in the optical heating apparatus, the optical system may include: a plurality of converging optical elements that is disposed to individually correspond to the plurality of LED elements, the plurality of converging optical elements each reducing a divergence angle of the light emitted by each of the plurality of LED elements; and a refractive optical element that is disposed between the plurality of converging optical elements and the substrate to be treated, and refracts light emitted from the plurality of converging optical elements, toward the central portion of the substrate to be treated.

The optical heating apparatus may further include: a chamber that houses the support unit, the light source unit, and the optical system; and a light transmissive window that is disposed between the substrate to be treated and the light source unit, and transmits the light emitted by the plurality of LED elements, and the light transmissive window may separate a space where the support unit is located from a space where the light source unit is located.

By employing the configuration described above, for example, even in a case where treatment solution for cleaning has been supplied to the substrate to be treated, the treatment solution can be prevented from coming into contact with the light source unit. As a result, malfunctions of the LED element can be prevented from occurring due to contact with the treatment solution, and this is preferable. Note that the present invention is not limited to an example where liquid such as treatment solution is supplied to the substrate to be treated. For example, in a case where process gas for treating the substrate to be treated is introduced into a space where the substrate to be treated is located, similarly, the light transmissive window exhibits a function of preventing the process gas from coming into contact with the light source unit.

In the optical heating apparatus, a separation distance between the substrate to be treated and the LED substrate in a normal direction of the main surface of the substrate to be treated may be 30 mm or less.

Details will be described in the section “DETAILED DESCRIPTION OF THE PREFERRED EMBODIMENTS”, but in a case where the light source unit includes a space facing the central portion of the substrate to be treated, the optical system exhibits a function of facilitating design to reduce the separation distance between the substrate to be treated and the LED substrate in the normal direction. In view of reducing the separation distance to reduce the footprint of the optical heating apparatus, the separation distance is preferably 30 mm or less, and more preferably, 20 mm or less.

Furthermore, in the optical heating apparatus, the support unit may be configured to be able to rotate the substrate to be treated in a circumferential direction, a region where the LED substrate and the substrate to be treated face each other may be a half or less of the main surface of the substrate to be treated, and the space may face more than half of the main surface of the substrate to be treated in a direction along the normal.

The configuration described above is suitable, because an increase in the communication space of the light source unit causes an increase in a degree of freedom of design in the optical heating apparatus.

According to the present invention, an optical heating apparatus that is capable of increasing the illuminance of heating light to be applied to a central portion of a substrate to be treated, even in a case where there is a restriction on the disposition of an LED element in a region that faces the central portion, is provided.

### BRIEF DESCRIPTION OF THE DRAWINGS

FIG. 1 is a side cross-sectional view illustrating a configuration example of an optical heating apparatus according to the present invention;

FIG. 2 is a plan view of a light source unit illustrated in FIG. 1 when viewed in a Z direction;

FIG. 3 is a diagram illustrating a portion of FIG. 2 in an enlarged manner;

FIG. 4 is a diagram illustrating, in an enlarged manner, a periphery of LED elements for which an optical system is disposed;

FIG. 5 is a diagram illustrating, in accordance with FIG. 1, a configuration of an optical heating apparatus according to a comparative example;

FIG. 6 is a side cross-sectional view illustrating, in accordance with FIG. 1, a configuration of an optical heating apparatus according to a second embodiment;

FIG. 7 is a diagram illustrating a variation of the second embodiment;

FIG. 8 is a cross-sectional view illustrating, in an enlarged manner, a periphery of LED elements for which an optical system is disposed;

FIG. 9 is a side cross-sectional view illustrating another configuration example of an optical heating apparatus;

FIG. 10 is a side cross-sectional view illustrating yet another configuration example of an optical heating apparatus;

FIG. 11 is a plan view of a light source unit illustrated in FIG. 10 when viewed in the Z direction;

FIG. 12 is a side cross-sectional view illustrating yet another configuration example of an optical heating apparatus; and

FIG. 13 is a side cross-sectional view illustrating yet another configuration example of an optical heating apparatus.

### DETAILED DESCRIPTION OF THE PREFERRED EMBODIMENTS

### First Embodiment

Hereinafter, an embodiment of an optical heating apparatus according to the present invention will be described with reference to the drawings. Note that each of the drawings described below is schematic illustration, and dimensional ratios or the numbers of components in the drawings do not necessarily coincide with actual dimensional ratios or the actual numbers of components.

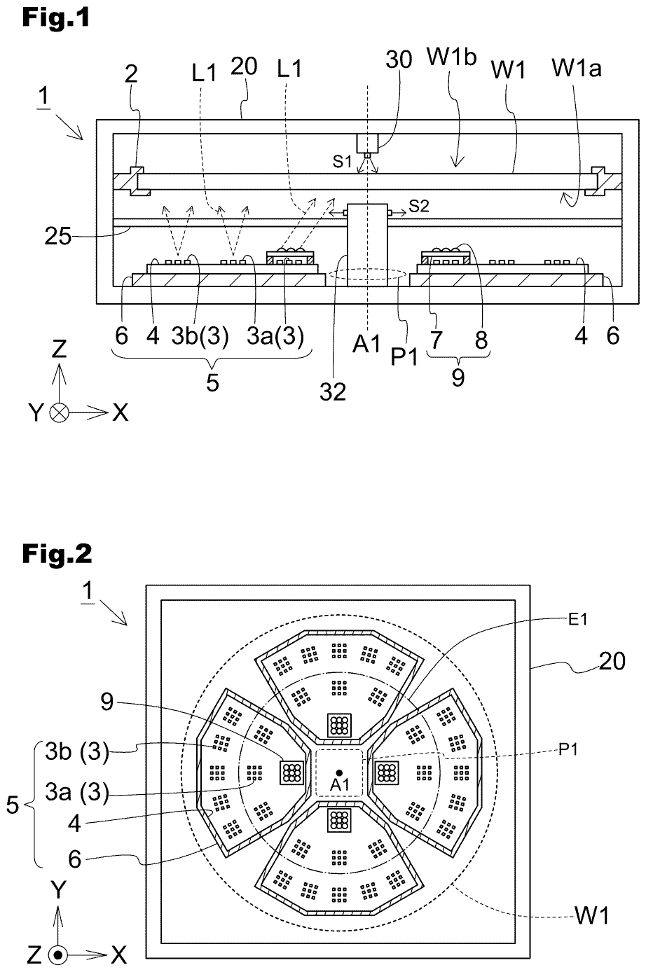

FIG. 1 is a side cross-sectional view illustrating a configuration example of an optical heating apparatus according to the present invention. An optical heating apparatus 1 irradiates a main surface W1a on a −Z side of a substrate to be treated W1 with heating light to perform heating treatment on the substrate to be treated W1. As illustrated in FIG. 1, the optical heating apparatus 1 includes a support unit 2, a light source unit 5, an optical system 9, and a chamber 20.

In the description below, an X-Y-Z coordinate system in which a normal direction of the main surface W1a of the substrate to be treated W1 is assumed to be a Z direction and a plane orthogonal to the Z direction is assumed to be an XY plane is appropriately referred to. Furthermore, in expressing directions, in a case where positive and negative directions are distinguished, the directions are described with a positive or negative symbol added, as described as a “+X direction” or a “−X direction”. In a case where a direction is expressed without distinguishing between positive and negative directions, the direction is simply described as an “X direction”. Stated another way, herein, in a case where a direction is simply described as the “X direction”, both the “+X direction” and the “−X direction” are included. The same is applied to a Y direction and the Z direction.

The support unit 2 is housed in the chamber 20, and supports the substrate to be treated W1, as illustrated in FIG. 1. As an example, the support unit 2 supports an end of the substrate to be treated W1. A configuration of the support unit 2 is not particularly limited, as long as the support unit 2 can support the substrate to be treated W1 in a state where the main surface W1a is parallel to the XY plane. For example, the support unit 2 may include a plurality of pin-shaped protrusions, and may support the substrate to be treated W1 by using the protrusions. Alternatively, the support unit 2 may be configured to support the substrate to be treated W1 by a negative pressure generated by a suction mechanism.

In the present embodiment, the support unit 2 is configured to be able to rotate the substrate to be treated W1 with a normal A1 at the center of the substrate to be treated W1 as a central axis, by using a not-illustrated rotation mechanism. A configuration of the rotation mechanism is not particularly limited, and any conventionally known configuration may be employed. As an example, the rotation speed of the substrate to be treated W1 is 20 rpm to 2000 rpm. As a more specific example, the rotation speed is 20 rpm to 100 rpm, 100 rpm to 1000 rpm, or 1000 rpm to 2000 rpm.

In the present embodiment, the substrate to be treated W1 is a semiconductor wafer such as a silicon substrate. The diameter of the main surface W1a of the substrate to be treated W1 is not particularly limited, but as an example, the diameter is 300 mm.

FIG. 2 is a plan view of the light source unit 5 illustrated in

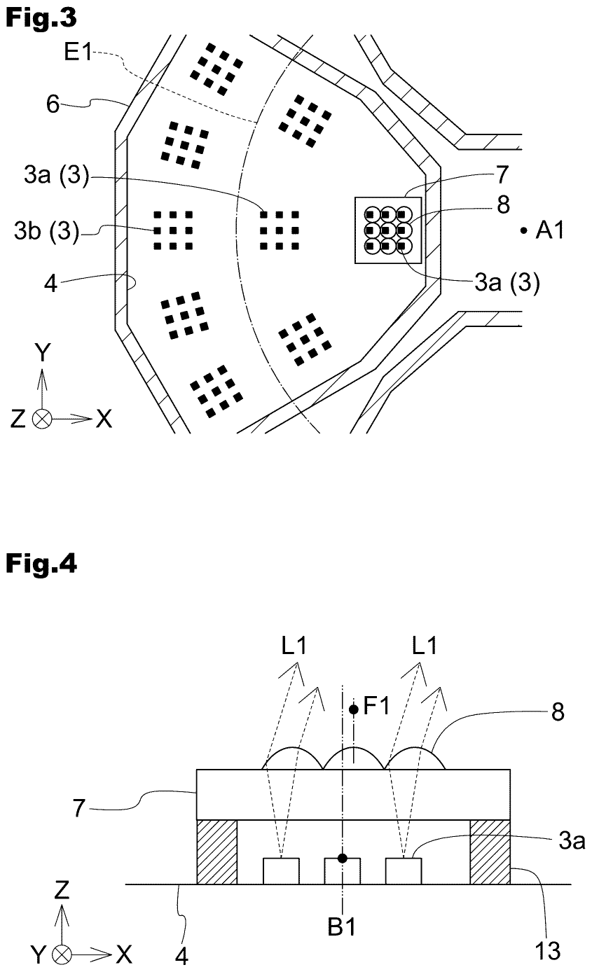

FIG. 1 when viewed in the Z direction. In FIG. 2, a light transmissive window 25 and a cleaning device 32 that will be described later are not illustrated, and a position of the substrate to be treated W1 is schematically illustrated with a broken line. In addition, FIG. 3 is a diagram illustrating a portion of FIG. 2 in an enlarged manner. The light source unit 5 includes a plurality of LED elements 3, 3, . . ., and an LED substrate 4 on which the plurality of LED elements 3 is arranged, as illustrated in FIGS. 2 and 3.

The plurality of LED elements 3 is arranged in a planar shape on a main surface of the LED substrate 4, as illustrated in FIG. 2, and emits heating light L1 in a +Z direction (see FIG. 1). The LED element 3 has, for example, isotropy, and has a quadrangular shape of 1 mm×1 mm when viewed in the Z direction. As an example, the length in the X direction of the LED element 3 is 0.5 mm to 2 mm, and the length in the Y direction is 0.5 mm to 2 mm. In addition, the LED element 3 may have a circular shape having a diameter of 1 mm when viewed in the Z direction. In a case where the LED element 3 has a circular shape, the diameter of the LED element 3 is, for example, 0.5 mm to 2 mm.

In FIGS. 2 and 3, a circumferential end portion E1 of the substrate to be treated W1 is illustrated. Here, the circumferential end portion E1 refers to a region where a distance in a radial direction from an end is 30% or less of the diameter of the main surface of the substrate to be treated W1, on the main surface of the substrate to be treated W1. In the present embodiment, the light source unit 5 includes LED elements 3a that are disposed on an inner side of the circumferential end portion E1 of the substrate to be treated W1, and LED elements 3b that are disposed to face the circumferential end portion E1, when viewed in the Z direction.

The wavelength of the heating light L1 emitted by the LED element (3a or 3b) is not particularly limited, and as an example, the peak wavelength of the heating light L1 falls within a range of 350 nm to 900 nm. As a more specific example, the peak wavelength may fall within one or more ranges of 350 nm to 500 nm, 500 nm to 700 nm, and 700 nm to 900 nm.

The LED substrate 4 supports the LED elements 3, as illustrated in FIG. 1. The LED substrate 4 is made of, for example, a ceramic material such as aluminum nitride or silicon nitride, and is disposed to extend on the XY plane. A main surface on the +Z side of the LED substrate 4 faces the main surface W1a of the substrate to be treated W1.

As illustrated in FIGS. 1 and 2, the LED substrate 4 is disposed such that it does not overlap with a portion of the substrate to be treated W1 along the Z direction. In the present embodiment, a plurality of the LED substrate 4 forms a communication space P1 in a vicinity of the normal A1 passing through the center of the substrate to be treated W1. The “vicinity of the normal A1” refers to a region where a distance from the normal A1 in the radial direction of the substrate to be treated W1 is 25% or less of the diameter of the substrate to be treated W1. As an example, a region where a distance from the normal A1 in the radial direction is 30 mm or less corresponds to a region in the vicinity of the normal A1. In FIGS. 1 and 2, the communication space P1 is schematically illustrated with a broken line.

In the present embodiment, the optical heating apparatus 1 includes a plurality of LED substrates 4 in a circumferential direction of the substrate to be treated W1 (see FIG. 1). As long as the light source unit 5 is configured to include a space facing the substrate to be treated W1 at least in a vicinity of the normal A1, the number of LED substrates 4 included in the optical heating apparatus 1 is not particularly limited. For example, the optical heating apparatus 1 may include a single annular LED substrate 4.

As an example, the LED substrate 4 is disposed on a heat sink 6, and is supported by the heat sink 6, as illustrated in FIG. 1. The heat sink 6 is made of, for example, a metal material such as copper, stainless steel, or aluminum. The heat sink 6 is disposed such that it does not overlap with a portion of the substrate to be treated W1 along the Z direction. Similarly to the LED substrate 4, a plurality of the heat sink 6 forms the communication space P1 in the vicinity of the normal A1 passing through the center of the substrate to be treated W1.

As illustrated in FIG. 1, it is preferable that a placement surface of the LED substrate 4 on which the LED elements 3a are arranged be parallel to the main surface W1a of the substrate to be treated W1. As a result, for example, even in a case where a cooling member, such as the heat sink 6, that is configured to promote the cooling down of the LED elements 3a is disposed on the −Z side of the LED substrate 4, the cooling member can be easily designed, and this is preferable.

The optical system 9 includes a lens substrate 7 that faces the LED substrate 4, and a lens element 8 formed on a main surface on the +Z side of the lens substrate 7, as illustrated in FIG. 1.

The lens substrate 7 is disposed on the +Z side of the LED substrate 4 to face the LED substrate 4 in the Z direction, as illustrated in FIGS. 1 and 3. Furthermore, the lens substrate 7 is disposed to overlap the plurality of LED elements 3a when viewed in the Z direction, and faces the plurality of LED elements 3a, as illustrated in FIG. 3.

The lens substrate 7 is made of, for example, a glass material such as quartz glass, and transmits the heating light L1 emitted by the LED element 3. Here, to “transmit the heating light” may mean that the light transmittance with respect to the heating light L1 is 80% or more.

FIG. 4 is a diagram illustrating, in an enlarged manner, a periphery of the LED elements 3a for which the optical system 9 is disposed. As illustrated in FIG. 4, a plurality of lens elements 8 is formed on the main surface on the +Z side of the lens substrate 7. The lens elements 8 are formed to correspond to the respective LED elements 3a. In the present embodiment, the lens element 8 has a shape that is convex on the +Z side. More specifically, the lens element 8 is a convex lens that has a spherical surface having a shape of a solid of revolution with a central axis that runs in the Z direction as a center. Note that the lens element 8 is not limited to a convex lens having a spherical surface. For example, the lens element 8 may be an aspherical lens. The lens element 8 corresponds to a “converging optical element”.

From the viewpoint of reducing an aberration and more accurately irradiating the substrate to be treated W1 with the heating light L1, the lens element 8 may be formed on a main surface on the −Z side of the lens substrate 7 and may have a shape that is convex on the −Z side.

As an example, the lens substrate 7 is fixed to a support member 13 that is disposed on the LED substrate 4, as illustrated in FIG. 4. It is preferable that the support member 13 be made of an insulating material. Examples of the insulating material include a ceramic material such as aluminum nitride and a glass material such as quartz glass. The support member 13 extends from the LED substrate 4 beyond the LED element 3 in the Z direction, as illustrated in FIG. 4. As a result, a separation distance can be secured between the LED elements 3a and the lens substrate 7, and the lens substrate 7 can be prevented from colliding with the LED elements 3a, and this is preferable. For example, the lens substrate 7 is bonded to the support member 13 by using an adhesive.

FIG. 4 schematically illustrates a focal point F1 of the lens element 8, and an optical axis B1 of the LED element 3a. Here, the optical axis of the LED element may refer to a normal that passes through the center of a light-emitting surface of each of the LED elements. As illustrated in FIG. 4, the lens element 8 is disposed in such a way that the focal point F1 of the lens element 8 is located closer to the normal A1 than the optical axis B1 of an LED element 3a that the lens element 8 corresponds to. FIG. 4 illustrates the LED elements 3a that are located on the −X side of the normal A1, but the same is applied to LED elements 3a that are located on the +X side of the normal A1.

Although not illustrated, the same is applied to LED elements 3a that are located on a +Y side of the normal A1 and LED elements 3a that are located on a −Y side of the normal A1. Stated another way, in the present embodiment, the focal point F1 of the lens element 8 that is disposed to correspond to the LED element 3a is located closer to the normal A1 than the optical axis B1 of the LED element 3a when viewed in the Z direction.

Furthermore, FIG. 4 schematically illustrates an aspect of traveling of the heating light L1 emitted by the LED element 3a. As illustrated in FIG. 4, the focal point F1 of the lens element 8 is located closer to the normal A1 than the optical axis B1 of a corresponding LED element 3a, and therefore the heating light L1 made incident on the lens element 8 is guided to approach the normal A1 of the substrate to be treated W1. Stated another way, the lens element 8 guides the heating light L1 toward a central portion of the substrate to be treated W1 while reducing the divergence angle of the heating light L1. As a result, a large amount of heating light L1 can be applied to the central portion of the substrate to be treated W1 (see also FIG. 1).

It is preferable that the optical system 9 be disposed for an LED element 3a that is disposed in a region where a distance from the normal A1 is 35% or less of the diameter of the substrate to be treated W1 in the radial direction of the substrate to be treated W1.

In the present embodiment, the optical heating apparatus 1 includes a nozzle 30 that supplies treatment solution S1 to the main surface W1a of the substrate to be treated W1, a light transmissive window 25 that is disposed between the substrate to be treated W1 and the LED elements 3a, and a cleaning device 32 that supplies cleaning solution S2 to a main surface on the +Z side of the light transmissive window 25, as illustrated in FIG. 1. The optical heating apparatus 1 irradiates the main surface W1a with the heating light L1 while supplying the treatment solution S1 to a main surface W1b on the +Z side of the substrate to be treated W1, and heats the substrate to be treated W1. The composition of the treatment solution S1 is not limited, but as an example, the treatment solution S1 exhibits a function of cleaning the main surface W1b or a function of modifying the main surface W1b.

From the viewpoint of preventing part of the treatment solution S1 that has spilled down from the main surface W1b from adhering to the light source unit 5 in supplying the treatment solution S1 to the main surface W1b, it is preferable that the optical heating apparatus 1 include the light transmissive window 25, as illustrated in FIG. 1. The light transmissive window 25 is made of, for example, a glass material such as quartz glass, and transmits the heating light L1. In addition, the light transmissive window 25 functions as a partition plate that separates a space in the chamber 20 into a space where the substrate to be treated W1 is located and a space where the light source unit 5 is located, as illustrated in FIG. 1. As a result, the light transmissive window 25 prevents the treatment solution S1 from adhering to the light source unit 5.

At this time, part of the treatment solution S1 adheres to the main surface on the +Z side of the light transmissive window 25. The cleaning device 32 is configured to be able to supply the cleaning solution S2 to the light transmissive window 25, and removes the treatment solution S1 that has adhered to the light transmissive window 25. As a result, it is possible to prevent the transmittance of the light transmissive window 25 from decreasing due to, for example, the contamination of the light transmissive window 25 caused by the adhesion of the treatment solution S1.

The cleaning device 32 is disposed in the communication space P1, as illustrated in FIG. 1. As described above, in a case where the LED substrate 4 forms the communication space P1 in the vicinity of the normal A1, and the cleaning device 32 that cleans the light transmissive window 25, for example, is disposed in the communication space P1, the LED elements 3a fail to be disposed in the communication space P1. In other words, the light source unit 5 has the communication space P1, and therefore an aspect of disposition of the LED elements 3a is restricted in a region that faces the central portion of the substrate to be treated W1.

In this case, heating light L1 to be applied to the central portion of the substrate to be treated W1, that is, the region that faces the communication region P1, is likely to be insufficient. In contrast, in the present embodiment, as described with reference to FIG. 4, the optical system 9 is disposed for the LED element 3a, and therefore the heating light L1 emitted by the LED element 3a is guided toward the normal A1, and on the main surface W1a of the substrate to be treated W1, a region that faces the communication region P1 can be irradiated with a larger amount of heating light L1. Stated another way, according to the present embodiment, even in a case where the LED elements 3a fail to be disposed in the region that faces the central portion of the substrate to be treated W1, the illuminance of heating light L1 to be applied to the central portion of the substrate to be treated W1 can be increased.

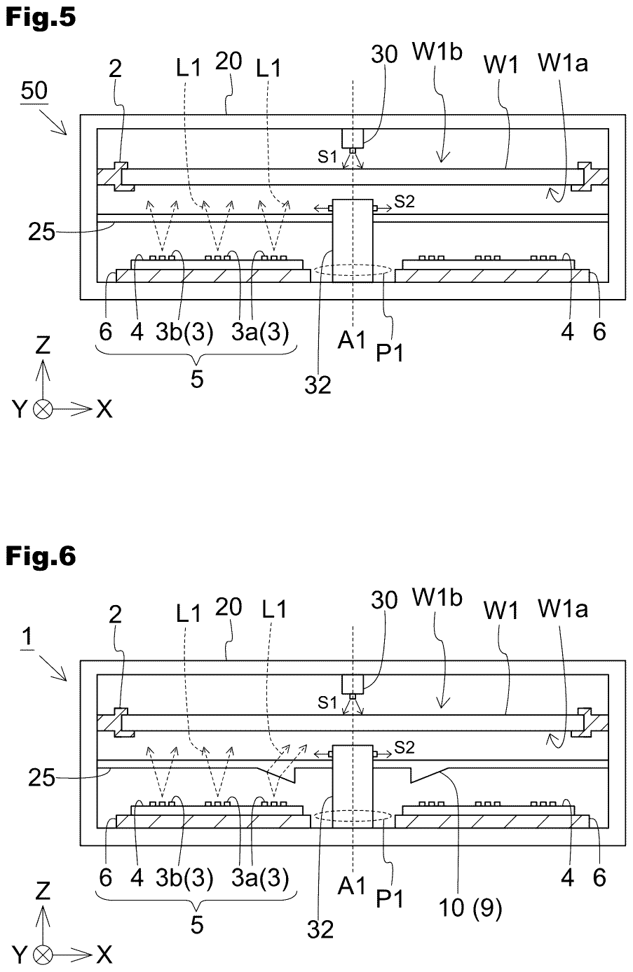

FIG. 5 is a diagram illustrating, in accordance with FIG. 1, a configuration of an optical heating apparatus according to a comparative example. An optical heating apparatus 50 illustrated in FIG. 5 is different from the first embodiment described above in that the optical system 9 is not disposed. In the optical heating apparatus 50, elements that are common to the optical heating apparatus 1 are denoted by identical reference signs. As illustrated in FIG. 5, in the optical heating apparatus 50, the cleaning device 32 is disposed in the communication space P1 of the LED substrate 4. Therefore, the LED elements 3a fail to be disposed in the communication space P1, and heating light L1 to be applied to the region that faces the communication space P1 is likely to be insufficient.

In contrast, as described with reference to FIG. 4, the optical system 9 is disposed for the LED element 3a, and therefore the heating light L1 emitted by the LED element 3a is guided to the region that faces the communication space P1, and the illuminance of heating light L1 to be applied to the central portion of the substrate to be treated W1 can be increased.

Furthermore, in FIG. 5, as a separation distance in the Z direction between the LED substrate 4 and the substrate to be treated W1 decreases, the heating light L1 emitted by the LED element 3a is less likely to be applied to the central portion of the substrate to be treated W1. This is because the heating light L1 diverges while exhibiting what is called Lambertian distribution. In view of the Lambertian distribution, an effective irradiation range of the LED element 3a can be said to be a range that is irradiated with heating light L1 having an emission angle of 30° or less with the optical axis B1 as a reference. It is assumed, for example, that the separation distance in the Z direction between the LED substrate 4 and the substrate to be treated W1 is 30 mm. In this case, the effective irradiation range of the LED element 3a on the substrate to be treated W1 is a range of about ±15 mm with the optical axis B1 as a reference. In other words, in a case where the light source unit 5 is configured to include a space in the vicinity of the normal A1 and the separation distance in the Z direction between the LED substrate 4 and the substrate to be treated W1 is 30 mm or less, heating light to be applied to the central portion of the substrate to be treated W1 is likely to be significantly insufficient.

In contrast, the heating light L1 is guided by using the optical system 9 (see FIG. 4), and therefore even in a case where the separation distance is 30 mm or less, the central portion of the substrate to be treated W1 can be suitably irradiated with the heating light L1. In a case where the light source unit 5 is configured to include a space in the vicinity of the normal A1, the optical system 9 facilitates design to reduce the separation distance in the Z direction between the LED substrate 4 and the substrate to be treated W1 in the optical heating apparatus 1. In view of reducing the separation distance to reduce the footprint of the optical heating apparatus 1, the separation distance is preferably 30 mm or less, and more preferably, 20 mm or less.

Note that although the cleaning device 32 has been described above as being disposed in the communication space P1, the present invention is not limited to such a configuration, as described later.

### Second Embodiment

Hereinafter, a second embodiment of an optical heating apparatus according to the present invention will be described focusing on differences from the first embodiment with reference to FIG. 6. FIG. 6 is a side cross-sectional side view illustrating, in accordance with FIG. 1, a configuration of an optical heating apparatus according to the second embodiment.

It has been described above that the optical system 9 is constituted by the lens substrate 7 and the lens element 8. However, as illustrated in FIG. 6, the optical system 9 may include a prism 10 that refracts the heating light L1. The prism 10 corresponds to a “refractive optical element”.

As an example, the prism 10 is formed on a main surface on the −Z side of the light transmissive window 25. The prism 10 has an inclined surface that is inclined relative to the LED substrate 4, and has a shape in which a separation distance from the LED substrate 4 in the Z direction decreases in a portion closer to the normal A1 in a direction parallel to the XY plane. Furthermore, for example, the prism 10 may have a shape of a solid of revolution with the normal A1 as a center.

As illustrated in FIG. 6, the prism 10 is disposed on the optical axes (not illustrated) of some of the LED elements 3a, and refracts the incident heating light L1 toward the normal A1. The optical system 9 including the prism 10 is disposed for the LED element 3a, as described above, and therefore the heating light L1 emitted by the LED element 3a can be guided to a region that faces the communication space P1. As a result, heating light L1 that travels toward the central portion of the substrate to be treated W1 increases, and the illuminance of heating light L1 to be applied to the central portion is increased.

The refractive index of the prism 10 and an angle of the inclined surface of the prism 10 relative to the LED substrate 4 can be appropriately adjusted. Furthermore, from the viewpoint of preventing total reflection in the prism 10, anti-reflective coating may be applied to the inclined surface.

An aspect of disposition of the LED elements (3a and 3b) can be discussed similarly to the first embodiment.

FIG. 6 illustrates an example where the prism 10 is formed on the main surface on the −Z side of the light transmissive window 25. However, this arrangement is not limiting, and the prism 10 may be formed on the main surface on the +Z side of the light transmissive window 25. Note that from the viewpoint of making it easy for the cleaning device 32 to clean the main surface on the +Z side of the light transmissive window 25, it is preferable that the prism 10 be formed on the main surface on the −Z side of the light transmissive window 25.

Furthermore, the present invention is not limited to the arrangement in which the prism 10 is formed on the main surface of the light transmissive window 25. For example, similarly to the description of the first embodiment, a substrate that faces the LED element 3a may be disposed, and a prism may be formed on the substrate.

In the present embodiment, the optical system 9 includes the prism 10, but the optical system 9 may include, for example, a Fresnel lens. In this case, the Fresnel lens corresponds to the “refractive optical element”.

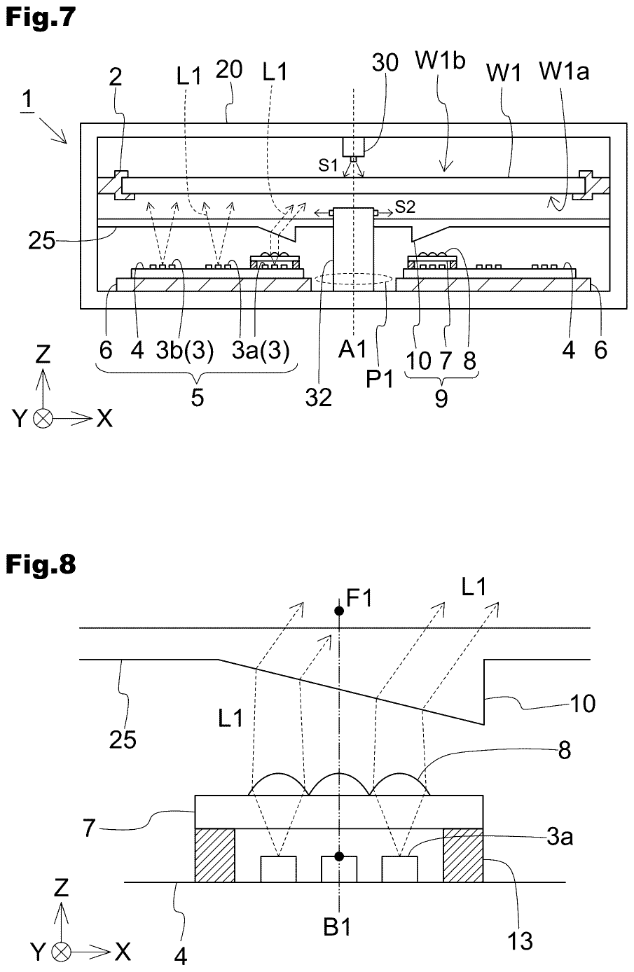

FIG. 7 is a diagram illustrating a variation of the second embodiment. As illustrated in FIG. 7, the optical system 9 may include the lens substrate 7, the lens element 8, and the prism 10.

FIG. 8 is a cross-sectional view illustrating, in an enlarged manner, a periphery of the LED elements 3a for which the optical system 9 is disposed. FIG. 8 schematically illustrates, in accordance with FIG. 4, the focal point F1 of the lens element 8 and the optical axis B1 of the LED element 3a. In the present variation, as illustrated in FIG. 8, the focal point F1 of the lens element 8 is located on the optical axis B1 of an LED element 3a that the lens element 8 corresponds to. FIG. 8 illustrates LED elements 3a that are located on the −X side of the normal A1, but a similar discussion can be made on an LED element 3a for which the prism 10 is disposed.

FIG. 8 schematically illustrates an aspect of traveling of the heating light L1 emitted by the LED element 3a. As illustrated in FIG. 8, the focal point F1 of the lens element 8 is located on the optical axis B1 of a corresponding LED element 3a, and therefore the divergence angle of heating light L1 made incident on the lens element 8 is reduced. Thereafter, the heating light L1 is made incident on the prism 10, and is guided to approach the normal A1 of the substrate to be treated W1. In a preceding stage of entering the prism 10, the divergence angle of the heating light L1 is reduced, and therefore a larger amount of heating light L1 can be made incident on the prism 10. As a result, a larger amount of heating light L1 is easily guided to a region that faces the communication region P1, that is, the central portion of the substrate to be treated W1, and this is preferable.

With reference to FIGS. 7 and 8, it has been described that the lens substrate 7 is disposed in a region that faces the LED element 3a, and the lens element 8 is formed on the lens substrate 7. However, the aspect of disposition of the lens element 8 is not limited thereto. For example, the lens element 8 may be integrated with each of the LED elements 3a. The lens element 8 corresponds to the “converging optical element”.

### Other Embodiments

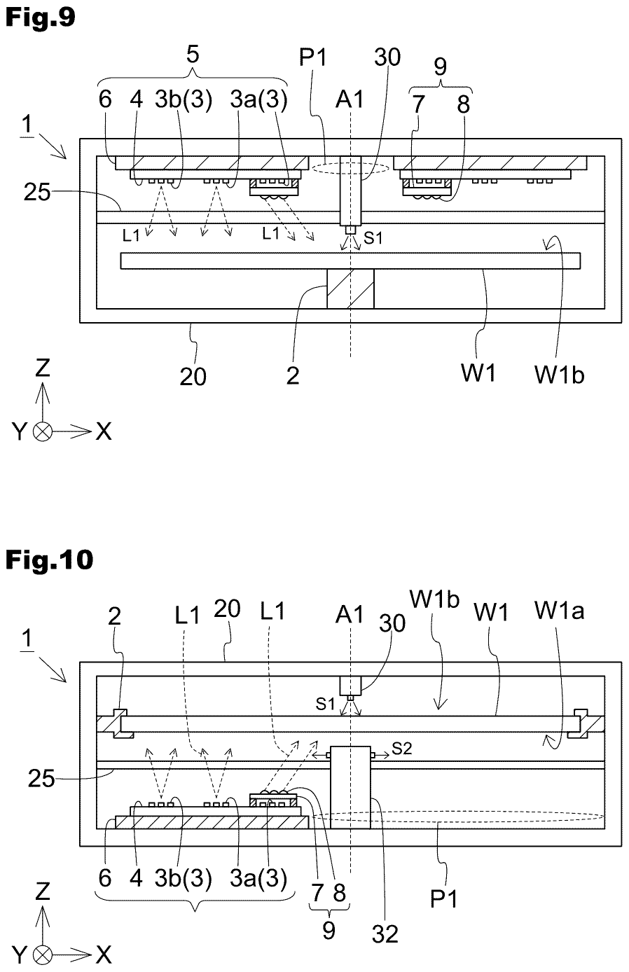

Other embodiments of the optical heating apparatus 1 will be described below.

<1> FIG. 9 is a side cross-sectional view illustrating, in accordance with FIG. 1, another configuration example of the optical heating apparatus 1. It has been described above that the light source unit 5 is disposed on the −Z side of the substrate to be treated W1, but as illustrated in FIG. 9, the light source unit 5 may be disposed on the +Z side of the substrate to be treated W1.

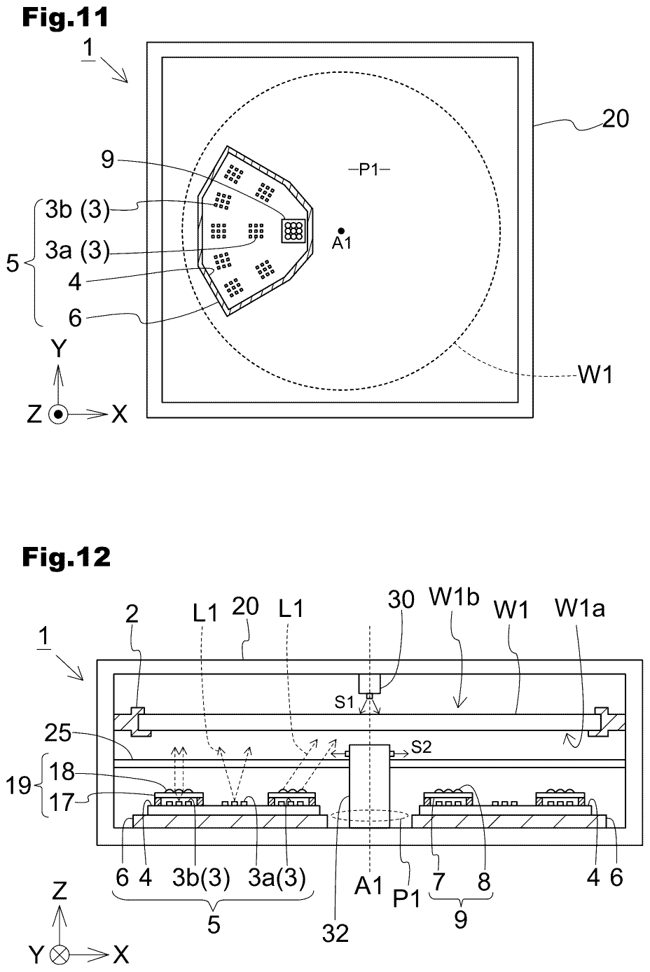

FIG. 9 illustrates an example where a nozzle 30 that supplies the treatment solution S1 to the main surface W1b of the substrate to be treated W1 is disposed in the communication space P1. Also in this case, as described with reference to FIG. 4, the focal point F1 of the lens element 8 is located closer to the normal A1 than the optical axis B1 of the LED element 3a, and therefore the heating light L1 can be guided to the central portion of the substrate to be treated W1.

<2> The present invention is not limited to a device that is disposed in the communication space P1. It has been described above that the cleaning device 32 or the nozzle 30 is disposed in the communication space P1, but this is merely an example. For example, a temperature sensor that measures the temperature of the substrate to be treated W1 in a non-contact manner may be disposed in the communication space P1, or a gas supply nozzle configured to adjust the atmosphere in the chamber 20 may be disposed. The present invention can be suitably applied to a case where a space facing the substrate to be treated is formed in the light source unit 5 at least in the vicinity of the normal A1 and there is a restriction on an aspect of disposition of the LED element particularly in a region that faces the central portion of the substrate to be treated W1.

<3> It has been described above that the optical heating apparatus 1 includes the light transmissive window 25 that prevents the LED element 3 from coming into contact with the treatment solution S1. However, it is optional whether the cleaning device 32 or the nozzle 30 is disposed in the communication space P1, and the present invention is not limited to a configuration including the light transmissive window 25. Similarly, the present invention is not limited to a configuration in which the support unit 2 rotates the substrate to be treated W1 in the circumferential direction.

<4> FIG. 10 is a side cross-sectional view illustrating, in accordance with FIG. 1, yet another configuration example of the optical heating apparatus 1. Furthermore, FIG. 11 is a plan view illustrating, in accordance with FIG. 2, a light source unit 5 illustrated in FIG. 10 when viewed in the Z direction. It has been described above that the light source unit 5 is configured to include a space facing the substrate to be treated W1 in the vicinity of the normal A1. However, as illustrated in FIGS. 10 and 11, the light source units 5 may be configured to include a space that faces the substrate to be treated W1 in a region wider than a vicinity of the normal A1 in the Z direction.

In the present embodiment, the support unit 2 is configured to be able to rotate the substrate to be treated W1 in the circumferential direction. In this case, a point that the heating light L1 of the LED element 3a that is disposed to face the optical system 9 can be guided toward the central portion of the substrate to be treated W1 can be discussed similarly to the first embodiment described above.

Furthermore, for example, a region where the LED substrate 4 and the substrate to be treated W1 face each other may be a half or less of the main surface W1a of the substrate to be treated W1. In other words, the light source unit 5 may be configured to include a space that faces more than half of the main surface W1a of the substrate to be treated W1 in the Z direction. It can be said that a degree of freedom of disposition of devices in the chamber 20 increases in a case where the communication space P1 is wide. In view of this, it is preferable that a region where the LED substrate 4 and the substrate to be treated W1 face each other be ¼ or less of the main surface W1a of the substrate to be treated W1, as illustrated in FIG. 11.

FIGS. 10 and 11 illustrate an example where the optical system 9 includes the lens substrate 7 and the lens element 8. However, as described in the second embodiment, the optical system 9 may include the prism 10.

<6> FIG. 12 is a side cross-sectional view illustrating, in accordance with FIG. 1, yet another configuration example of the optical heating apparatus 1. From the viewpoint of reducing a ratio of heating light L1 traveling in a direction different from the direction of the substrate to be treated W1 relative to heating light L1 emitted by the LED element 3b, an optical system 19 that faces the LED element 3b and reduces the divergence angle of the heating light L1 emitted by the LED element 3b may be included, as illustrated in FIG. 12. For example, the optical system 19 includes a lens substrate 17 that faces the LED element 3b, and a lens element 18 formed on the lens substrate 17. The lens element 18 is formed to individually correspond to the LED element 3b.

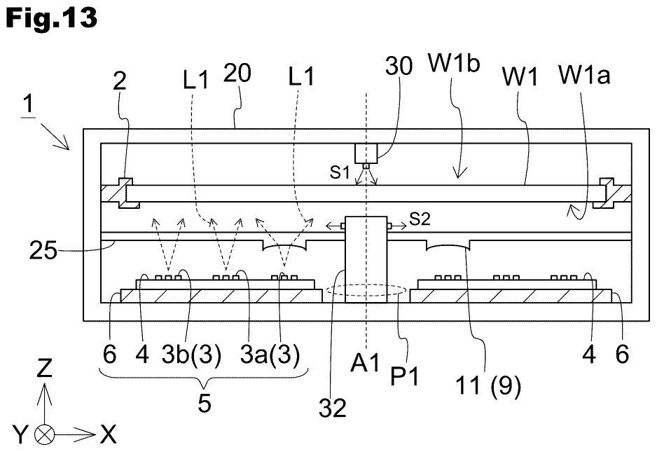

Note that the optical system 9 is disposed for some of the LED elements 3a that are disposed on an inner side of the circumferential end portion of the substrate to be treated W1, similarly to the embodiments described above.

<7> FIG. 13 is a side cross-sectional view illustrating yet another configuration example of the optical heating apparatus 1. The optical system 9 may be a diffusing optical element that diffuses heating light L1. As illustrated in FIG. 13, the optical system 9 may be constituted by a concave lens 11. By diffusing the heating light L1 emitted by the LED element 3a, the heating light L1 can also be guided toward the central portion of the substrate to be treated W1.

<8> A configuration of the optical heating apparatus 1 is not limited to the configurations described above. Furthermore, the configurations of the embodiments described above and the variations can be appropriately combined and embodied.

### DESCRIPTION OF REFERENCE SIGNS

1 Optical heating apparatus
2 support unit
3, 3a, 3b LED element
4 LED substrate
5 light source unit
6 heat sink
7 lens substrate
8 lens element
9 optical system
10 prism
11 concave lens
13 support member
17 lens substrate
18 lens element
19 optical system
20 chamber
25 light transmissive window
30 nozzle
32 cleaning device
50 optical heating apparatus
A1 normal
B1 optical axis
E1 circumferential end portion
F1 focal point
L1 heating light
P1 communication space
S1 treatment solution
S2 cleaning solution
W1 substrate to be treated

What is claimed is:

1. An optical heating apparatus that irradiates a substrate to be treated with light, and heats the substrate to be treated, the optical heating apparatus comprising:
a support unit that supports the substrate to be treated;
a light source unit that includes an LED substrate that is disposed to face a portion of a main surface of the substrate to be treated, and a plurality of LED elements that is placed on the LED substrate; and
an optical system that is disposed between the substrate to be treated and the LED substrate, and refracts at least a portion of light emitted by each of the plurality of LED elements, toward a central portion of the substrate to be treated,
wherein the light source unit is configured to include a space facing the substrate to be treated at least in a vicinity of a normal passing through a center of the main surface of the substrate to be treated.

2. The optical heating apparatus according to claim 1, wherein
the optical system includes a plurality of converging optical elements that is disposed to individually correspond to the plurality of LED elements, the plurality of converging optical elements each reducing a divergence angle of the light emitted by each of the plurality of LED elements, and
when viewed in a normal direction of the main surface of the substrate to be treated, a focal point of each of the plurality of converging optical elements is located closer to a center of the substrate to be treated than a center of a light-emitting surface of the LED element that each of the plurality of converging optical elements corresponds to.

3. The optical heating apparatus according to claim 1, wherein
the optical system includes:
a plurality of converging optical elements that is disposed to individually correspond to the plurality of LED elements, the plurality of converging optical elements each reducing a divergence angle of the light emitted by each of the plurality of LED elements; and
a refractive optical element that is disposed between the plurality of converging optical elements and the substrate to be treated, and refracts light emitted from the plurality of converging optical elements, toward the central portion of the substrate to be treated.

4. The optical heating apparatus according to claim 1, further comprising:
a chamber that houses the support unit, the light source unit, and the optical system; and
a light transmissive window that is disposed between the substrate to be treated and the light source unit, and transmits the light emitted by the plurality of LED elements,
wherein the light transmissive window separates a space where the support unit is located from a space where the light source unit is located.

5. The optical heating apparatus according to claim 2, further comprising:
a chamber that houses the support unit, the light source unit, and the optical system; and
a light transmissive window that is disposed between the substrate to be treated and the light source unit, and transmits the light emitted by the plurality of LED elements,
wherein the light transmissive window separates a space where the support unit is located from a space where the light source unit is located.

6. The optical heating apparatus according to claim 3, further comprising:
a chamber that houses the support unit, the light source unit, and the optical system; and
a light transmissive window that is disposed between the substrate to be treated and the light source unit, and transmits the light emitted by the plurality of LED elements,
wherein the light transmissive window separates a space where the support unit is located from a space where the light source unit is located.

7. The optical heating apparatus according to claim 1, wherein a separation distance between the substrate to be treated and the LED substrate in a normal direction of the main surface of the substrate to be treated is 30 mm or less.

8. The optical heating apparatus according to claim 2, wherein a separation distance between the substrate to be treated and the LED substrate in a normal direction of the main surface of the substrate to be treated is 30 mm or less.

9. The optical heating apparatus according to claim 3, wherein a separation distance between the substrate to be treated and the LED substrate in a normal direction of the main surface of the substrate to be treated is 30 mm or less.

10. The optical heating apparatus according to claim 1, wherein
the support unit is configured to be able to rotate the substrate to be treated in a circumferential direction,
a region where the LED substrate and the substrate to be treated face each other is a half or less of the main surface of the substrate to be treated, and
the space faces more than half of the main surface of the substrate to be treated in a direction along the normal.

11. The optical heating apparatus according to claim 2, wherein
the support unit is configured to be able to rotate the substrate to be treated in a circumferential direction,
a region where the LED substrate and the substrate to be treated face each other is a half or less of the main surface of the substrate to be treated, and
the space faces more than half of the main surface of the substrate to be treated in a direction along the normal.

12. The optical heating apparatus according to claim 3, wherein
the support unit is configured to be able to rotate the substrate to be treated in a circumferential direction,
a region where the LED substrate and the substrate to be treated face each other is a half or less of the main surface of the substrate to be treated, and
the space faces more than half of the main surface of the substrate to be treated in a direction along the normal.
